(19) United States
(12) Patent Application Publication
(10) Pub. No.: US 2011/0001543 A1
(43) Pub. Date: Jan. 6, 2011

(54) SEMICONDUCTOR INTEGRATED CIRCUIT DEVICE

(75) Inventors: Masao KONDO, Kanagawa (JP); Satoshi GOTO, Kanagawa (JP); Masatoshi MORIKAWA, Kanagawa (JP)

Correspondence Address: MATTINGLY & MALUR, P.C., 1800 DIAGONAL ROAD, SUITE 370, ALEXANDRIA, VA, 22314, US

(73) Assignee: RENESAS ELECTRONICS CORPORATION, Kanagawa (JP)

(21) Appl. No.: 12/813,852

(22) Filed: Jun. 11, 2010

(30) Foreign Application Priority Data
Jul. 3, 2009 (JP) 2009-158995

(51) Int. Cl. H03K 17/56; H01L 27/12

(52) U.S. Cl. 327/419; 257/296; 257/347; 257/E27.112

(57) ABSTRACT

SOI MOSFETs are used for the transistors for switching of an antenna switch and yet harmonic distortion is significantly reduced. Capacitance elements are respectively added to either the respective drains or gates of the transistors comprising the through MOSFET group of reception branch of the antenna switch. This makes the voltage amplitude between source and gate and that between drain and gate different from each other. As a result, the voltage dependence of source-drain parasitic capacitance becomes asymmetric with respect to the polarity of voltage. This asymmetry property produces signal distortion having similar asymmetry property. Therefore, the following can be implemented by setting it so that it has the same amplitude as that of second-harmonic waves arising from the voltage dependence of substrate capacitance and a phase opposite to that of the same: second-order harmonic distortion can be canceled out and thus second-order harmonic distortion can be reduced.

### CROSS-REFERENCE TO RELATED APPLICATIONS

The disclosure of Japanese Patent Application No. 2009-158995 filed on Jul. 3, 2009 including the specification, drawings and abstract is incorporated herein by reference in its entirety.

### BACKGROUND OF THE INVENTION

The present invention relates to technologies for reducing harmonic distortion in antenna switches used in mobile communication devices or the like and in particular to a technology effectively applicable to the reduction of second-order harmonic distortion and third-order harmonic distortion in an antenna switch configured using SOI MOSFETs (Silicon On Insulator Metal Oxide Semiconductor Field Effect Transistors).

In antenna switches for switching between transmission and reception used in cellular phones or the like, in general, a compound semiconductor FET such as HEMT (High Electron Mobility Transistor) is used as a transistor for switching. It is known that SOI MOSFET is used as this transistor for switching to meet a demand for manufacturing cost reduction and the like.

In case of SPDT (Single Pole Double Throw)-type antenna switch, for example, there are provided a through MOSFET group of transmission branch, a shunting MOSFET group of transmission branch, a through MOSFET group of reception branch, and a shunting MOSFET group of reception branch.

The through MOSFET group of transmission branch is comprised of multiple MOSFETs coupled in series between a transmission terminal and an antenna terminal and the gate of each MOSFET is respectively coupled with one coupling portion of a resistor.

The shunting MOSFET group of transmission branch is comprised of multiple MOSFETs coupled in series between the transmission terminal and reference potential VSS and the gate of each MOSFET is respectively coupled with one coupling portion of a resistor.

The through MOSFET group of reception branch is comprised of multiple MOSFETs coupled in series between a reception terminal and the antenna terminal and the gate of each MOSFET is respectively coupled with one coupling portion of a resistor.

The shunting MOSFET group of reception branch is comprised of multiple MOSFETs coupled in series between the reception terminal and the reference potential VSS and the gate of each MOSFET is respectively coupled with one coupling portion of a resistor.

The through MOSFET group of transmission branch, shunting MOSFET group of transmission branch, through MOSFET group of reception branch, and shunting MOSFET group of reception branch each include, for example, five SOI n-channel MOSFETs.

The other coupling portions of the resistors respectively coupled to the through MOSFET group of transmission branch and the shunting MOSFET group of reception branch are respectively supplied with direct-current voltage VTX. The other coupling portions of the resistors respectively coupled to the through MOSFET group of reception branch and the shunting MOSFET group of transmission branch are respectively supplied with direct-current voltage VRX.

In transmission mode; the direct-current voltage VTX is positive and the direct-current voltage VRX is negative. As a result, the through MOSFET group of transmission branch and the shunting MOSFET group of reception branch are brought into on state and the through MOSFET group of reception branch and the shunting MOSFET group of transmission branch are brought into off state.

In reception mode, the direct-current voltage VTX is negative and the direct-current voltage VRX is positive. As a result, the through MOSFET group of transmission branch and the shunting MOSFET group of reception branch are brought into off state and the through MOSFET group of reception branch and the shunting MOSFET group of transmission branch are brought into on state.

As an antenna switch configured using this type of SOI MOSFETs, the following antenna switch is known: an antenna switch in which, instead of a silicon (Si) substrate, for example, a sapphire substrate is used as a supporting substrate for a SOI layer to reduce the substrate capacitance associated with a source-drain diffusion layer to reduce second-order harmonic distortion. (Refer to Patent Document 1.)

In the technology disclosed in Patent Document 1, further, the following is implemented by providing a body with a electrode for controlling its potential and applying negative potential to the body: the junction capacitance between a source diffusion layer and a drain diffusion layer and the body is reduced and third-order harmonic distortion is thereby reduced.

[Patent Document 1] Japanese Unexamined Patent Application Publication (Translation of PCT Application) No. 2009-500868

### SUMMARY OF THE INVENTION

However, the present inventors found that switching technologies based on the above-mentioned antenna switch using SOI MOSFETs involved the following problems:

When SOI MOSFETs are used for the transistors for switching in an antenna switch circuit, harmonic distortion becomes larger than in cases where compound semiconductor FETs are used for this purpose.

FIG. 28 is an explanatory drawing illustrating the relation between input power and produced second-order harmonic distortion power in a case where SOI MOSFETs examined by the present inventors are used and a case where compound semiconductor FETs are used. FIG. 29 is an explanatory drawing illustrating the relation between input power and produced third-order harmonic distortion power in a case where the SOI MOSFETs examined by the present inventors are used and a case compound semiconductor FETs are used.

As indicated in the drawings, the produced second-order harmonic distortion is larger by approximately 10 dB when SOI MOSFETs are used than when compound semiconductor FETs are used and the third-order harmonic distortion is larger by approximately 15 dB.

A major cause of the production of second-order harmonic distortion observed when SOI MOSFETs are used is in that: the parasitic capacitance (substrate capacitance) between the source-drain diffusion layer of the SOI MOSFETs and the Si substrate under a BOX oxide film has voltage dependence.

A major cause of the production of third-order harmonic distortion is in that: the junction capacitance between the source diffusion layer and drain diffusion layer of the SOI MOSFETs and the body (semiconductor layer directly under a gate) located between them has voltage dependence.

Compound semiconductor FETs are formed over a semi-insulating substrate. Therefore, they are significantly smaller than SOI MOSFETs in the above-mentioned substrate capacitance and junction capacitance and as a result, harmonic distortion is also small.

Further, according to the technology disclosed in Patent Document 1, as mentioned above, SOI MOSFETs are used as transistors for switching and yet harmonic distortion is reduced to the same level as in cases where compound semiconductor FETs are used.

However, substrates obtained by forming a SOI layer over sapphire (SOS (Silicon On Sapphire) substrates) are more expensive than SOI substrates and it is impossible to meet a demand for manufacturing cost reduction.

A method of supplying a body with negative potential can reduce third-harmonic waves but cannot reduce second-harmonic waves.

It is an object of the invention to provide a technology wherein it is possible to use SOI MOSFETs for the transistors for switching of an antenna switch and yet significantly reduce harmonic distortion.

The above and other objects and novel features of the invention will be apparent from the description in this specification and the accompanying drawings.

The following is a brief description of the gist of the representative elements of the invention laid open in this application:

An aspect of the invention is a semiconductor integrated circuit device including at least one antenna terminal, at least one transmission terminal, and at least one reception terminal and provided with an antenna switch for switching signal paths. The antenna switch includes: a first transistor group coupled between the antenna terminal and the transmission terminal; a second transistor group coupled between the antenna terminal and the reception terminal; a third transistor group coupled between the transmission terminal and reference potential; a fourth transistor group coupled between the reception terminal and the reference potential; and a first capacitance element. The first to fourth transistor groups are each comprised of one or more transistors coupled in series. The first capacitance element is coupled between the gate and source or between the gate and drain of at least one transistor comprising the first to fourth transistor groups.

In an aspect of the invention, the first capacitance element is coupled to a transistor provided in the second transistor group.

An aspect of the invention is a semiconductor integrated circuit device including at least one antenna terminal, at least one transmission terminal, and at least one reception terminal and provided with an antenna switch for switching signal paths. The antenna switch includes: a first transistor group coupled between the antenna terminal and the transmission terminal; a second transistor group coupled between the antenna terminal and the reception terminal; a third transistor group coupled between the transmission terminal and reference potential; a fourth transistor group coupled between the reception terminal and the reference potential; a second capacitance element; and a third capacitance element. The first to fourth transistor groups are each comprised of one or more transistors coupled in series. The second capacitance element is coupled between the gate and source of at least one transistor comprising the first to fourth transistor groups and the third capacitance element is coupled between the gate and drain of a transistor. The second capacitance element and the third capacitance element are different from each other in capacitance value.

In an aspect of the invention, the second and third capacitance elements are coupled to a transistor provided in the second transistor group.

An aspect of the invention is a semiconductor integrated circuit device including at least one antenna terminal, at least one transmission terminal, and at least one reception terminal and provided with an antenna switch for switching signal paths. The antenna switch includes: a first transistor group coupled between the antenna terminal and the transmission terminal; a second transistor group coupled between the antenna terminal and the reception terminal; a third transistor group coupled between the transmission terminal and reference potential; a fourth transistor group coupled between the reception terminal and the reference potential; and a fourth capacitance element. The first to fourth transistor groups are each comprised of one or more transistor coupled in series. The fourth capacitance element has voltage dependence in capacitance value and is coupled between the source and drain of at least one transistor comprising the first to fourth transistor groups.

In an aspect of the invention, the fourth capacitance element is formed by coupling two MOS capacitors and the coupling portions of the two MOS capacitors are coupled to reference potential or supply voltage through a resistor.

In an aspect of the invention, the antenna switch includes a fifth capacitance element. One coupling portion of the fifth capacitance element is coupled to the gate of at least one transistor comprising the first to fourth transistor groups; and the other coupling portion is coupled to the node of the coupling portions of the two MOS capacitors of the fourth capacitance element.

In an aspect of the invention, the fourth capacitance element is coupled to a transistor provided in the second transistor group.

An aspect of the invention is a semiconductor integrated circuit device including at least one antenna terminal, at least one transmission terminal, and at least one reception terminal and provided with an antenna switch for switching signal paths. The antenna switch includes: a first transistor group coupled between the antenna terminal and the transmission terminal; a second transistor group coupled between the antenna terminal and the reception terminal; a third transistor group coupled between the transmission terminal and reference potential; a fourth transistor group coupled between the reception terminal and the reference potential; and a sixth capacitance element. The first to fourth transistor groups are each comprised of one or more transistors coupled in series. One coupling portion of the sixth capacitance element is coupled to the source or drain of at least one transistor comprising the first to fourth transistor groups; and the other coupling portion is coupled to the reference potential through a resistor.

In an aspect of the invention, the antenna switch includes a seventh capacitance element. One coupling portion of the seventh capacitance element is coupled to the gate of at least one transistor comprising the first to fourth transistor groups; and the other coupling portion is coupled to the coupling node between the sixth capacitance element and a resistor.

In an aspect of the invention, the sixth capacitance element is coupled to a transistor provided in the second transistor group.

In an aspect of the invention, the fifth and seventh capacitance elements are each comprised of a MOS capacitor.

In an aspect of the invention, the first to seventh capacitance elements are formed over an SOI substrate.

The following is a brief description of the gist of other aspects of the invention laid open in this application:

In an aspect of the invention, the fourth capacitance element is formed of a MOS capacitor and is comprised of a gate electrode, a gate oxide film located directly under the gate electrode, and a silicon substrate. The silicon substrate region around the gate electrode is made higher in impurity concentration than the silicon substrate region located directly under the gate electrode.

In an aspect of the invention, the fourth capacitance element is obtained by electrically coupling gate electrodes together to form one gate terminal and providing one terminal in the high-impurity concentration silicon substrate region around each gate electrode.

In an aspect of the invention, the transistors comprising the first to fourth transistor groups are formed over an SOI substrate.

The following is a brief description of the gist of effects obtained by the representative elements of the invention laid open in this application:

(1) It is possible to significantly reduce second-order harmonic distortion and third-order harmonic distortion in an antenna switch configured using SOI MOSFETs.

(2) Owing to Section (1) above, it is possible to significantly reduce the manufacturing cost of an antenna switch and yet enhance the performance of the antenna switch.

### BRIEF DESCRIPTION OF THE DRAWINGS

FIG. 1 is a block diagram illustrating an example of the configuration of a transmission/reception unit provided in a cellular phone in a first embodiment of the invention;

FIG. 2 is a circuit diagram illustrating an example of the antenna switch provided in the transmission/reception unit in FIG. 1;

FIG. 3 is a circuit diagram illustrating an example of a through MOSFET group of reception branch comprising the antenna switch in FIG. 2;

FIG. 4 is a schematic diagram illustrating an example of the layout in the through MOSFET group of reception branch in FIG. 3;

FIG. 5 is an explanatory drawing illustrating the voltage dependence of the substrate capacitance of SOI MOSFET;

FIG. 6 is an explanatory drawing illustrating the voltage dependence of the source-drain parasitic capacitance of SOI MOSFET;

FIG. 7 is a circuit diagram illustrating an example of a through MOSFET group of reception branch in a second embodiment of the invention;

FIG. 8 is an explanatory drawing illustrating an example of the layout in a capacitance element for reducing second-order harmonic distortion provided in the through MOSFET group of reception branch in FIG. 7;

FIG. 9 is an explanatory drawing illustrating the voltage dependence of the capacitance value of the capacitance element in FIG. 8;

FIG. 10 is an explanatory drawing illustrating an example of a section taken along line a-b of FIG. 8;

FIG. 11 is a symbol diagram representing the capacitance element in FIG. 8;

FIG. 12 is an explanatory drawing illustrating an example of the plane layout of the through MOSFET group of reception branch in FIG. 7;

FIG. 13 is a circuit diagram illustrating an example of a through MOSFET group of reception branch in a third embodiment of the invention;

FIG. 14 is an explanatory drawing illustrating an example of the layout in a capacitance element for reducing second-order harmonic distortion provided in the through MOSFET group of reception branch in FIG. 13;

FIG. 15 is an explanatory drawing illustrating the voltage dependence of the source-drain parasitic capacitance of SOI MOSFET without an added capacitive element;

FIG. 16 is a circuit diagram illustrating an example of a through MOSFET group of reception branch in a fourth embodiment of the invention;

FIG. 17 is an explanatory drawing illustrating the voltage dependence of the capacitance value of a capacitance element for reducing third-order harmonic distortion provided in the through MOSFET group of reception branch in FIG. 16;

FIG. 18 is an explanatory drawing illustrating an example of the layout in a capacitance element provided in the through MOSFET group of reception branch in FIG. 16;

FIG. 19 is an explanatory drawing illustrating a section taken along line a-b of FIG. 18;

FIG. 20 is a symbol diagram representing the capacitance element in FIG. 18;

FIG. 21 is an explanatory drawing illustrating an example of the plane layout of the through MOSFET group of reception branch in FIG. 16;

FIG. 22 is a circuit diagram illustrating a through MOSFET group of reception branch in a fifth embodiment of the invention;

FIG. 23 is an explanatory drawing illustrating an example of the plane layout of the through MOSFET group of reception branch in FIG. 22;

FIG. 24 is a circuit diagram illustrating an example of a through MOSFET group of reception branch in a sixth embodiment of the invention;

FIG. 25 is an explanatory drawing illustrating an example of the plane layout of the through MOSFET group of reception branch in FIG. 24;

FIG. 26 is a circuit diagram illustrating an example of a through MOSFET group of reception branch in a seventh embodiment of the invention;

FIG. 27 is an explanatory drawing illustrating an example of the plane layout of the through MOSFET group of reception branch in FIG. 26;

FIG. 28 is an explanatory drawing of the second-order harmonic distortion characteristic of an antenna switch configured using the SOI MOSFETs examined by the present inventors and that of an antenna switch configured using compound semiconductor FETs; and

FIG. 29 is an explanatory drawing of the third-order harmonic distortion characteristic of an antenna switch configured using the SOI MOSFETs examined by the present inventors and that of an antenna switch configured using compound semiconductor FETs.

### DETAILED DESCRIPTION OF THE PREFERRED EMBODIMENTS

Hereafter, detailed description will be given to embodiments of the invention with reference to the drawings. In all the drawings for explaining embodiments, members having the same function will be marked with the same reference numerals as a rule and the repetitive description thereof will be omitted.

### First Embodiment

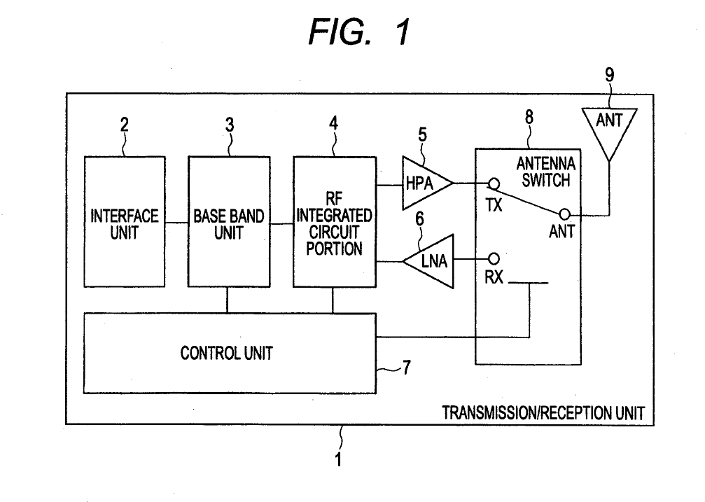

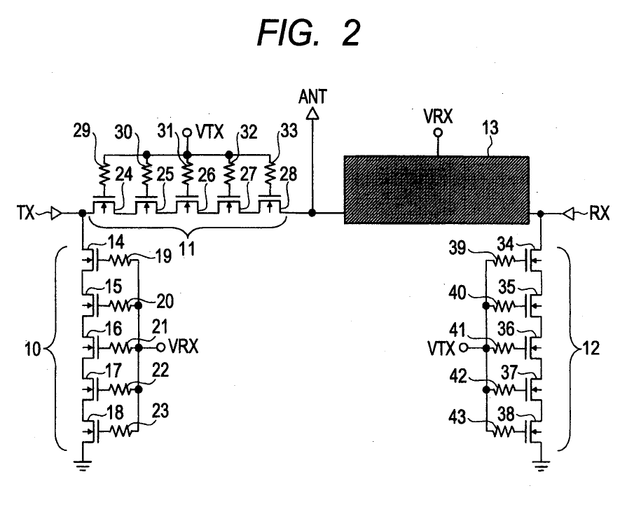

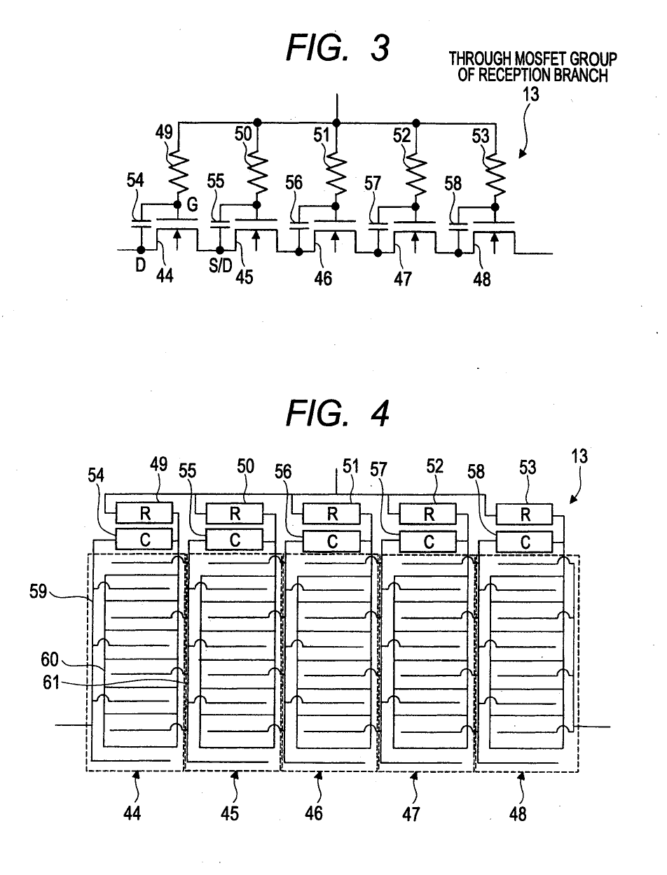

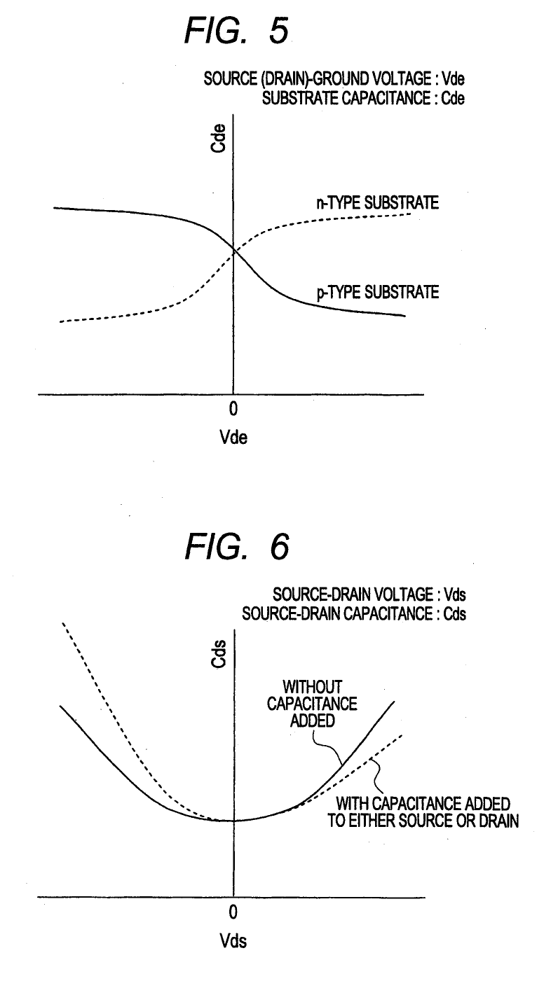

FIG. 1 is a block diagram illustrating an example of the configuration of a transmission/reception unit provided in a cellular phone in the first embodiment of the invention; FIG. 2 is a circuit diagram illustrating an example of an antenna switch provided in the transmission/reception unit in FIG. 1; FIG. 3 is a circuit diagram illustrating an example of a through MOSFET group of reception branch comprising the antenna switch in FIG. 2; FIG. 4 is a schematic diagram illustrating an example of the layout in the through MOSFET group of reception branch in FIG. 3; FIG. 5 is an explanatory drawing illustrating the voltage dependence of the substrate capacitance of SOI MOSFET; and FIG. 6 is an explanatory drawing illustrating the voltage dependence of the source-drain parasitic capacitance of SOI MOSFET.

In the first embodiment, the transmission/reception unit 1 used in, for example, a cellular phone is provided with the following members as illustrated in FIG. 1: an interface unit 2, a base band unit 3, an RF integrated circuit portion 4, a power amplifier 5, a low noise amplifier 6, a control unit 7, an antenna switch 8, an antenna 9, and the like.

The interface unit 2 interfaces with a circuit provided in the stage subsequent to the transmission/reception unit 1. The base band unit 3 converts transmit data into an I signal or a Q signal and outputs a control signal to carry out control on the RF integrated circuit portion or other like processing. The RF integrated circuit portion 4 demodulates received signals and modulates transmitted signals.

The power amplifier 5 amplifies transmitted signals outputted from the RF integrated circuit portion 4 and the low noise amplifier 6 amplifies received signal received by the antennal 9. The control unit 7 controls the base band unit 3, RF integrated circuit portion 4, and antenna switch 8.

The antenna switch 8 switches signals to be transmitted or received based on a control signal from the control unit 7. This antenna switch 8 is a SPDT switch provided with an antenna terminal ANT, a transmission terminal TX, and a reception terminal RX. The antennal 9 transmits or receives signal waves.

As illustrated in FIG. 2, the antenna switch 8 is comprised of: a shunting MOSFET group of transmission branch 10, a through MOSFET group of transmission branch 11, a shunting MOSFET group of reception branch 12, and a through MOSFET group of reception branch 13.

The shunting MOSFET group of transmission branch 10 is comprised of transistors 14 to 18 each formed of SOI n-channel MOSFET and resistors 19 to 23; and the through MOSFET group of transmission branch 11 is comprised of transistors 24 to 28 each formed of an n-channel MOSFET and resistors 29 to 33. The shunting MOSFET group of reception branch 12 is comprised of transistor 34 to 38 each formed of SOI n-channel MOSFET and resistors 39 to 43.

In the shunting MOSFET group of transmission branch 10, the transistor 14 to 18 are coupled in series between the transmission terminal TX and reference potential VSS. The respective gates of the transistors 14 to 18 are respectively coupled with the respective one coupling portions of the resistors 19 to 23. The respective other coupling portions of the resistors 19 to 23 are coupled with a control terminal VRX to which a control signal for reception outputted from the control unit 7 is applied.

In the through MOSFET group of transmission branch 11, the transistors 24 to 28 are coupled in series between the transmission terminal TX and the antenna terminal ANT. The respective gates of the transistors 24 to 28 are respectively coupled with the respective one coupling portions of the resistors 29 to 33. The respective other coupling portions of the resistors 29 to 33 are coupled with a control terminal VTX to which a control signal for transmission outputted from the control unit 7 is applied.

In the shunting MOSFET group of reception branch 12, the transistors 34 to 38 are coupled in series between the reception terminal RX and the reference potential VSS. The respective gates of the transistors 34 to 38 are respectively coupled with the respective one coupling portions of the resistors 39 to 43. The respective other coupling portions of the resistors 39 to 43 are coupled with the control terminal VTX to which a control signal for transmission outputted from the control unit 7 is applied.

The transistors 14 to 18 comprise a third transistor group; the transistors 24 to 28 comprise a first transistor group; and the transistors 34 to 38 comprise a fourth transistor group.

FIG. 3 is a circuit diagram illustrating an example of the through MOSFET group of reception branch 13.

The through MOSFET group of reception branch 13 is comprised of transistors 44 to 48 each formed of SOI n-channel MOSFET, resistors 49 to 53, and capacitance elements 54 to 58.

The transistors 44 to 48 comprise a second transistor group and the capacitance elements 54 to 58 form a first capacitance element.

The transistors 44 to 48 are coupled in series between the reception terminal RX and the antenna terminal ANT and the respective gates of the transistors 44 to 48 are respectively coupled with the respective one coupling portions of the resistors 49 to 53.

The respective other coupling portions of the resistors 49 to 53 are coupled with the control terminal VRX to which a control signal for reception outputted from the control unit 7 is applied. The respective one coupling portions of the capacitance elements 54 to 58 are respectively coupled with the respective gates of the transistors 44 to 48. The respective other coupling portions of the capacitance elements 54 to 58 are respectively coupled with the respective one coupling portions of the transistors 44 to 48.

In the antenna switch 8, the section between the antenna terminal ANT and the transmission terminal TX is a transmission branch and the section between the antenna terminal ANT and the reception terminal RX is a reception branch.

In transmission mode, the control signal to the control terminal VTX is of positive voltage. As a result, the transistors 24 to 28 in the through MOSFET group of transmission branch 11 and the transistors 34 to 38 in the shunting MOSFET group of reception branch 12 are brought into on state.

The control signal to the control terminal VRX is of negative voltage. As a result, the transistors 44 to 48 in the through MOSFET group of reception branch 13 and the transistors 14 to 18 in the shunting MOSFET group of transmission branch 10 are brought into off state.

In reception mode, the control terminal VTX is at negative voltage. As a result, the transistors 24 to 28 in the through MOSFET group of transmission branch 11 and the transistors 34 to 38 in the shunting MOSFET group of reception branch 12 are brought into off state.

The control terminal VRX is at positive voltage. As a result, the transistors 44 to 48 in the through MOSFET group of reception branch 13 and the transistors 14 to 18 in the shunting MOSFET group of transmission branch 10 are brought into on state.

The capacitance elements 54 to 58 are added to compensate second-harmonic waves and each comprised of a capacitive element (MIM (Metal-Insulator-Metal) capacitor) formed of two wiring layers and an interlayer film placed in-between.

FIG. 4 is an explanatory drawing illustrating an example of the layout of the through MOSFET group of reception branch 13 in FIG. 2.

From left to right in the upper part of FIG. 4, the resistors 49 to 53 are arranged and under the resistors 49 to 53, the capacitance elements 54 to 58 are respectively arranged. Under the capacitance elements 54 to 58, the transistors 44 to 48 are respectively arranged (in the areas encircled with broken lines in the drawing).

In the layout area of the transistor 44 encircled with a broken line, a drain wiring 59 is formed on the left side and a gate wiring 60 is formed on the right side thereof. On the right side of the layout area of the transistor 44 encircled with the broken line, there is formed the source wiring 61 of the transistor 44. This source wiring 61 is a common wiring and is also used as the drain wiring of the adjacent transistor 45.

The transistor 44 is comprised of multiple branched MOSFET transistors arranged in parallel. The respective drains of the branches are coupled together by the comb-like drain wiring 59 and the respective sources of the branches are coupled together by the comb-like source wiring 61.

As mentioned above, the source wiring 61 is also coupled with the drain of each branch of the adjacent transistor 45. The respective gates of the branches are coupled together by the ladder-structured gate wiring 60 and bundled with the gate wirings of the other transistors 45 to 48 through the resistors 49 to 53 to form a single terminal. The capacitance element 54 is coupled with the drain wiring 59 and the gate wiring 60.

The capacitance value of each of the capacitance elements 54 to 58 is so set that the following is implemented: signal distortion caused by the positive and negative asymmetric voltage dependence of source-drain parasitic capacitance arising from the capacitance value compensates second-order harmonic distortion. Unlike the other embodiments described later, none of the capacitance elements 54 to 58 necessarily requires voltage dependence in capacitance value.

In this case, the following can be implemented as compared with cases where none of the capacitance elements 54 to 58 is provided: second-order harmonic distortion can be reduced by approximately 10 dB substantially without influence on the characteristics, such as the third-harmonic waves, loss, and isolation, other than second-harmonic waves of the antenna switch 8.

Description will be give to why the capacitance elements 54 to 58 can compensate the influence of the voltage dependence of parasitic capacitance in the transistors 44 to 48.

A major cause of second-order harmonic distortion is in the voltage dependence of the parasitic capacitance (substrate capacitance) between the source/drain diffusion layer of a transistor formed of SOI MOSFET and the silicon substrate located under a BOX oxide film.

Usually, a silicon substrate is coupled to reference potential VSS and the high-frequency signal of the antenna switch 8 has an amplitude with its center at 0V identical with the reference potential VSS. In this case, a voltage amplitude with its center at 0V is applied to the substrate capacitance.

Since the spread of a depletion layer in the silicon substrate located under the BOX oxide film differs depending on the polarity of applied voltage, the substrate capacitance asymmetrically varies relative to the polarity of applied voltage. When the substrate is set to 0V and voltage is applied to a source or a drain, the substrate capacitance has the voltage dependence illustrated in FIG. 5. That is, it is increased with increase in voltage when the silicon substrate is of n type and is reduced with increase in voltage when the silicon substrate is of p type.

The voltage fluctuation of the parasitic capacitance of a device produces similarly asymmetric signal distortion.

Therefore, because of the voltage dependence of the substrate capacitance, harmonic distortion asymmetric with respect to the polarity of voltage amplitude, that is, even-order harmonic distortion is produced in the high-frequency signal of the antenna switch 8. The second-order harmonic distortion is the largest distortion element thereof.

The antenna switch 8 is provided with a mechanism for producing a second-harmonic wave having a phase opposite to that of this second-order harmonic distortion and substantially the same amplitude as that of the same. Thus, since the original second-order harmonic distortion is canceled out, the absolute value of the second-harmonic wave can be reduced. For this reason, the voltage dependence of source-drain parasitic capacitance becomes asymmetric with respect to the polarity of voltage by providing the capacitance elements 54 to 58 as illustrated in FIG. 3.

The reason for this will be described below.

FIG. 6 is an explanatory drawing illustrating a difference in the voltage dependence of source-drain parasitic capacitance depending on the presence or absence of the capacitance elements. The source-drain parasitic capacitance is obtained by coupling a parallel coupling of source-gate parasitic capacitance and source-body parasitic capacitance and a parallel coupling of drain-gate parasitic capacitance and drain-body parasitic capacitance in series.

These four different kinds of parasitic capacitance have voltage dependence and the voltage dependence of source-drain parasitic capacitance become symmetric with respect to the polarity of voltage when source-gate voltage amplitude and drain-gate voltage amplitude are equal to each other.

Addition of a capacitive element to either between source and gate or between drain and gate makes source-gate voltage amplitude and drain-gate voltage amplitude different from each other. As a result, the voltage dependence of source-drain parasitic capacitance becomes asymmetric with respect to the polarity of voltage.

This asymmetry property produces signal distortion having the same asymmetry property. Therefore, second-order harmonic distortion can be canceled out by so setting it that it has the same amplitude as that of second-harmonic waves arising from the voltage dependence of substrate capacitance and a phase opposite to that of the same.

The amplitude is optimized by adjusting the added capacitance value and the phase is optimized according to whether a capacitive element is coupled between source and gate or between drain and gate. Second-order harmonic distortion can also be reduced by adding capacitive elements having different values between source and gate and between drain and gate for the same reason as mentioned above.

According to the first embodiment, as mentioned above, second-harmonic waves in the antenna switch 8 configured using SOI MOSFETs can be significantly reduced by adding the capacitance elements 54 to 58.

Since the capacitance elements 54 to 58 are just added, a manufacturing cost, chip size, or the like is hardly increased and the inexpensive and high-performance antenna switch 8 can be obtained.

To produce signal distortion from the capacitance elements, it is required that voltage between drain and gate should fluctuate in transmission state. In the first embodiment, therefore, the capacitance elements 54 to 58 for compensating second-harmonic waves are added to the transistors 44 to 48 that are brought into off state in transmission mode in which a problem of harmonic distortion arises. Also when these capacitance elements 54 to 58 are added to the transistors 14 to 18 in the shunting MOSFET group of transmission branch 10, a favorable effect can be obtained.

However, if the capacitance value of each of the capacitance elements 54 to 58 is not sufficiently smaller than the parasitic capacitance of the transistors 14 to 18, there is a possibility that other characteristic than second-order harmonic distortion characteristic of the switch circuit is degraded. Therefore, it is usually desirable to add them to the through MOSFET group of reception branch 13 that is larger in gate width. This method for selecting a MOSFET group to which the capacitive elements are added applies not only to the first embodiment but also to all the following embodiments.

In the first embodiment, the capacitance elements 54 to 58 are respectively provided between the respective gates and drains of the transistors 44 to 48. However, second-harmonic waves can also be significantly reduced by, for example, the following measure: capacitance elements (second capacitance elements, third capacitance elements) different in capacitance are respectively provided between the respective gates and drains and between the respective gates and sources of the transistors 44 to 48.

### Second Embodiment

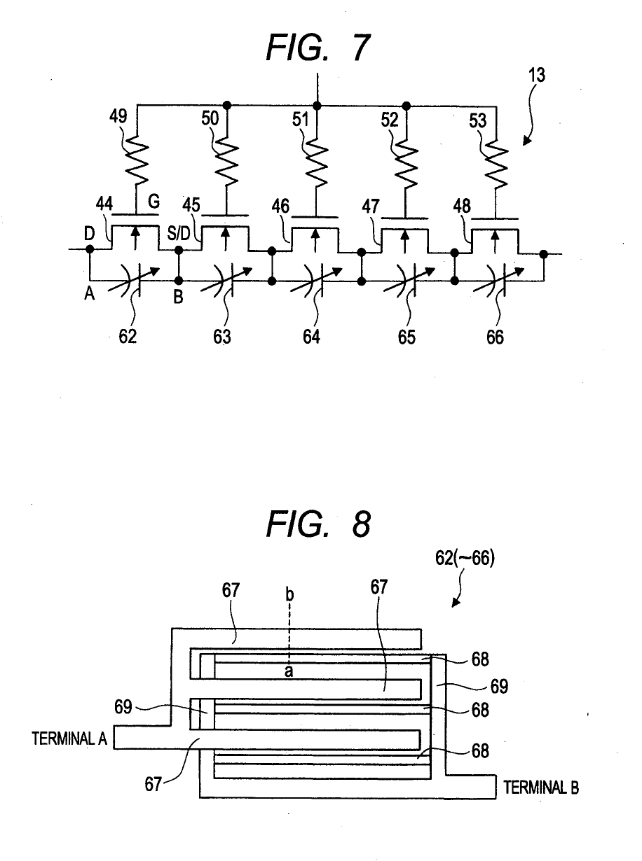

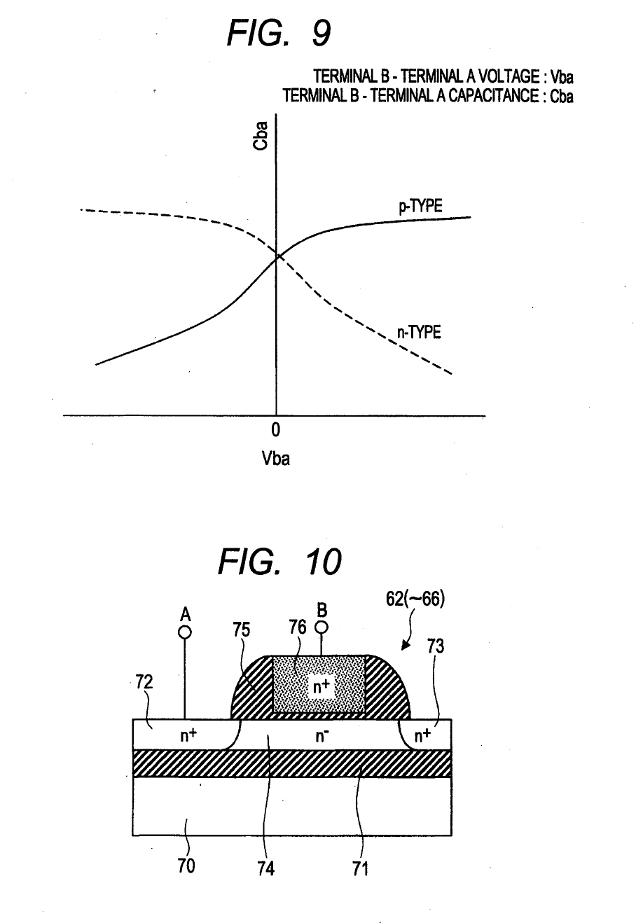

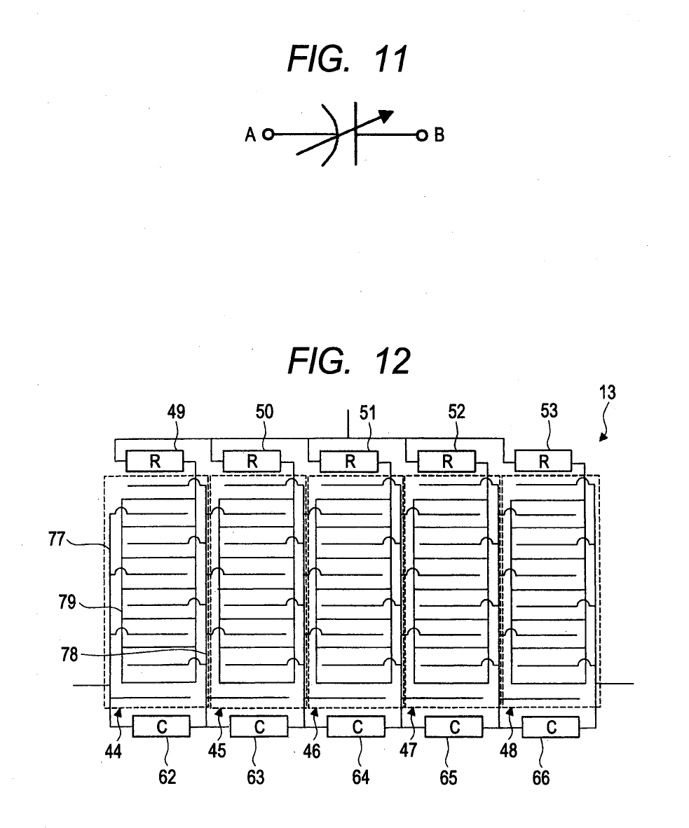

FIG. 7 is a circuit diagram illustrating an example of a through MOSFET group of reception branch in the second embodiment of the invention; FIG. 8 is an explanatory drawing illustrating an example of the layout in a capacitance element for reducing second-order harmonic distortion provided in the through MOSFET group of reception branch in FIG. 7; FIG. 9 is an explanatory drawing illustrating the voltage dependence of the capacitance value of the capacitance element in FIG. 8; FIG. 10 is an explanatory drawing illustrating an example of a section taken along line a-b of FIG. 8; FIG. 11 is a symbol diagram representing the capacitance element in FIG. 8; and FIG. 12 is an explanatory drawing illustrating an example of the plane layout of the through MOSFET group of reception branch in FIG. 7.

With respect to the second embodiment, description will be given to a technology for adding the following capacitance element to between the source and drain of a transistor of the antenna switch 8 which transistor is turned off in a desired circuit operation mode: a capacitance element having voltage dependence asymmetric with respect to the polarity of voltage.

This asymmetry property produces signal distortion having the same asymmetry property. Therefore, second-order harmonic distortion can be canceled out by so setting it that it has the same amplitude as that of second-harmonic waves arising from the voltage dependence of substrate capacitance and a phase opposite to that of the same. The amplitude is optimized by adjusting the added capacitance value and its voltage dependence and the phase is optimized by selection of orientation in which a capacitive element having polarity is inserted into between source and drain.

In this case, the antenna switch 8 is comprised as in FIG. 2 in relation to the first embodiment. That is, the antenna switch 8 is comprised of a shunting MOSFET group of transmission branch 10, a through MOSFET group of transmission branch 11, a shunting MOSFET group of reception branch 12, and a through MOSFET group of reception branch 13.

However, the circuitry of the through MOSFET group of reception branch 13 is different from that in the first embodiment. As illustrated in FIG. 7, the through MOSFET group of reception branch 13 is comprised of transistors 44 to 48 each formed of SOI n-channel MOSFET, resistors 49 to 53, and capacitance elements 62 to 66. The capacitances elements 62 to 66 form a fourth capacitance element.

How the transistors 44 to 48 and the resistors 49 to 53 are coupled with each other is the same as in FIG. 3. Between the respective sources and drains of the transistors 44 to 48, the capacitance elements 62 to 66 for compensation having desired voltage dependence are respectively coupled.

FIG. 8 is an explanatory drawing illustrating an example of the planar structure of the capacitance element 62 (to 66).

The capacitance element 62 (to 66) is comprised of, for example, three branched MOS capacitance elements, illustrated in FIG. 8, arranged in parallel.

On the left side of FIG. 8, terminal A equivalent to the source of a transistor is formed. This terminal A is coupled to source wirings 67 formed in a comb shape from top to bottom of FIG. 8. Between the source wirings 67 formed in a comb shape, gate electrodes 68 are respectively formed. These gate electrodes 68 are coupled to gate wirings 69 formed both on the right side and on the left side and coupled to terminal B in common.

In the capacitance element 62 (to 66) formed of a MOS capacitor, the thickness of the depletion layer located under a gate oxide film is varied by applying voltage to between the above-mentioned terminal A and terminal B. Therefore, voltage dependence occurs in capacitance value.

FIG. 9 indicates the relation between voltage Vba between terminals and capacitance value observed when terminal A is brought to 0V and the voltage of the terminal B is varied.

When the impurity added to the source/drain and the body (low-impurity concentration silicon layer) is of n type and negative voltage is applied to the terminal B, the width of the depletion layer under the gate oxide film is expanded; therefore, the capacitance is reduced.

When positive voltage is applied to the terminal B and its value is increased, the depletion layer located under the gate oxide film disappears and an electron accumulation layer is formed; therefore, the capacitance value is slightly increased and then becomes substantially constant. When the impurity added to the source/drain and the body is of n type, the impurity has the dependence obtained by inverting that with the p-type impurity with 0V taken as the center. In either case, the voltage dependence is asymmetric with respect to the polarity of voltage.

The magnitude of this voltage dependence can be varied by adjusting the impurity concentration of the body located under the gate oxide film. Therefore, the following effect can be obtained by adjusting the impurity concentration and gate width of a capacitance element to optimize the amount of voltage change in its capacitance value and the position where the capacitance element is coupled and the polarity: the effect of canceling out second-order harmonic distortion arising from the voltage dependence of substrate capacitance can be obtained. Since the absolute value of a capacitance value can be made relatively small by optimization, addition of this capacitive element does not have great influence on any characteristic other than the even-order harmonic distortion characteristic.

FIG. 10 is an explanatory drawing illustrating an example of a section taken along line a-b of FIG. 8.

The capacitance element 62 (to 66) is formed of, for example, a MOS capacitor. Over a high-resistance silicon substrate 70, there is formed a silicon oxide film (BOX oxide film) 71. On the left side and right side of the area over this silicon oxide film 71, there are respectively formed high-impurity concentration silicon layers 72, 73 similar to the source/drain of a transistor.

Over the silicon oxide film 71, a low-impurity concentration silicon layer (body) 74 is formed so that it is sandwiched between the high-impurity concentration silicon layers 72, 73. Over the low-impurity concentration silicon layer 74, there is formed a high-impurity concentration polycrystalline silicon film 76 to be a gate with a silicon oxide film (gate oxide film) 75 in-between.

The structure of the MOS capacitor is close to that of an ordinary MOSFET. However, it is different from the ordinary MOSFET in that: the impurity added to the portions of the high-impurity concentration silicon layers 72, 73 equivalent to source/drain and the impurity added to the body of the low-impurity concentration silicon layer 74 are identical with each other in conductivity type.

Desired voltage dependence can be obtained by adjusting the impurity concentration and distribution of the low-impurity concentration silicon layer. The impurity concentration is approximately 1×10¹⁷ cm⁻³ to 1×10¹⁸ cm⁻³. A desired absolute value of capacitance change due to voltage can be obtained by adjusting the width of the high-impurity concentration polycrystalline silicon film 76.

To reduce second-harmonic waves, the following measure is taken: a two-terminal element with the portion of its MOS capacitor equivalent to source (high-impurity concentration silicon layer 72) taken as the terminal A and the gate (high-impurity concentration polycrystalline silicon film 76) taken as the terminal B is used; and it is coupled to the source or drain and gate or the source and drain of MOSFET. FIG. 11 illustrates a circuit diagram symbol representing the two-terminal element in the capacitance element 62 (to 66).

The width of the gate (high-impurity concentration polycrystalline silicon film 76) is set to approximately ⅕ or below of the gate width of SOI MOSFET to prevent the characteristic of MOSFET to which it is added from being largely influenced. The length of the gate (high-impurity concentration polycrystalline silicon film 76) is set to approximately 1 μm or below to prevent the resistance of the low-impurity concentration silicon layer 74 from becoming prominent as the parasitic resistance of a capacitance element.

FIG. 12 is an explanatory drawing illustrating an example of the plane layout of the through MOSFET group of reception branch 13.

From left to right in the upper part of FIG. 12, the resistors 49 to 53 are arranged and under the resistors 49 to 53, the transistors 44 to 48 are respectively arranged. Under the transistors 44 to 48, the capacitance elements 62 to 66 are respectively arranged.

In the transistor 44 (encircled with a broken line in the drawing), multiple branched SOI MOSFETs are arranged in parallel. The respective drains of the branches are coupled together by a comb-like drain wiring 77 and the respective sources of the branches are coupled together by a comb-like source wiring 78.

The source wiring 78 is also coupled to the respective drains of the branches of the adjacent transistor 45. The respective gates of the branches are coupled together by a ladder-structured gate wiring 79. They are bundled with the gate wirings of the other transistors 45 to 48 through the resistors 49 to 53 to form a single terminal.

As mentioned above, the capacitance elements 62 to 66 are placed on the opposite side to the resistors 49 to 53 with the transistors 44 to 48 in-between and the drain wiring 77 and the source wiring 78 are coupled therethrough.

The capacitance value of each of the capacitance elements 62 to 66 and its voltage dependence are so set that signal distortion thereby produced compensates second-order harmonic distortion. For this purpose, the impurity concentration of the low-impurity concentration silicon layer 74 in FIG. 10 is controlled to approximately 5×10¹⁷ cm⁻³; and the width of the high-impurity concentration polycrystalline silicon film 76 to be a gate is designed to approximately 1/10 of the gate width of the transistors 44 to 48.

In this case, the following can be implemented as compared with cases where none of the capacitance elements 62 to 66 is added: second-order harmonic distortion can be reduced by approximately 10 dB substantially without influence on the characteristics, such as the third-harmonic waves, loss, and isolation, other than second-harmonic waves of the antenna switch 8.

### Third Embodiment

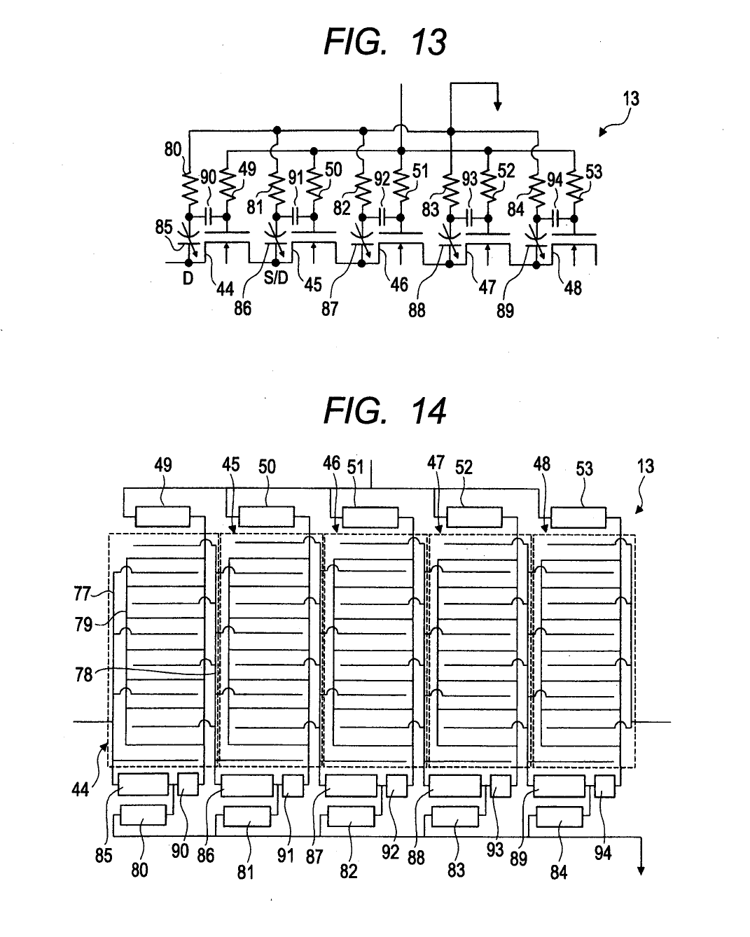

FIG. 13 is a circuit diagram illustrating an example of a through MOSFET group of reception branch in the third embodiment of the invention; and FIG. 14 is an explanatory drawing illustrating an example of the layout in a capacitance element for reducing second-order harmonic distortion provided in the through MOSFET group of reception branch in FIG. 13.

In the third embodiment, capacitance elements differing in voltage dependence depending on the polarity of voltage are inserted. The capacitance elements are inserted into between the respective sources and ground or between the respective drains and ground of the transistors 44 to 48 in the through MOSFET group of reception branch 13. The voltage dependence of each of these capacitance elements is set so as to compensate the influence of the voltage dependence of substrate capacitance asymmetric with respect to the polarity of voltage on the circuit characteristics.

The antenna switch 8 is comprised as in FIG. 2 in relation to the first embodiment. That is, the antenna switch 8 is comprised of a shunting MOSFET group of transmission branch 10, a through MOSFET group of transmission branch 11, a shunting MOSFET group of reception branch 12, and a through MOSFET group of reception branch 13.

Also in this case, the circuitry of the through MOSFET group of reception branch 13 is different from that in the first and second embodiments. As illustrated in FIG. 13, the through MOSFET group of reception branch 13 is comprised of transistors 44 to 48 each formed of SOI n-channel MOSFET, resistors 49 to 53, 80 to 84, and capacitance elements 85 to 94.

The capacitance elements 85 to 89 form a fifth capacitance element and the capacitance elements 90 to 94 form a sixth capacitance element.

How the transistors 44 to 48 and the resistors 49 to 53 are coupled together is the same as in FIG. 3. The respective drains of the transistors 44 to 48 are respectively coupled with the respective one coupling portions of the capacitance elements 85 to 89.

The respective other coupling portions of the capacitance elements 85 to 89 are respectively coupled with the respective one coupling portions of the resistors 80 to 84 and the respective one coupling portions of the capacitance elements 90 to 94. The respective other coupling portions of these resistors 80 to 84 are respectively coupled with reference potential VSS.

The respective gates of the transistors 44 to 48 are respectively coupled with the respective other coupling portions of the capacitance elements 90 to 94. The capacitance elements 90 to 94 function as to short-circuit their nodes to a gate for alternating current.

FIG. 14 is an explanatory drawing illustrating an example of the plane layout in the through MOSFET group of reception branch 13 in FIG. 13.

From left to right in the upper part of FIG. 14, the resistors 49 to 53 are arranged and under the resistors 49 to 53, the transistors 44 to 48 are respectively arranged.

On the left side of the area under the transistor 44 (encircled with a broken line in the drawing), there is placed the capacitance element 85 and on the right side of the capacitance element 85, there is placed the capacitance element 90. Also in the other transistors 45 to 48, the capacitance elements 86 to 89 and the capacitance elements 91 to 94 are similarly arranged.

The transistor 44 is comprised of multiple branched MOSFETs arranged in parallel. The respective drains of the branches are coupled together by the comb-like drain wiring 77 and the respective sources of the branches are coupled together by the comb-like source wiring 78.

The source wiring 78 is also coupled to the respective drains of the branches of the adjacent transistor 45. The respective gates of the branches are coupled together by the ladder-structured gate wiring 79. They are bundled with the gate wirings of the other transistors 44 to 48 through the resistors 49 to 53 to form a single terminal.

As illustrated in the drawing, the capacitance elements 85 to 89, resistors 80 to 84, and capacitance elements 90 to 94 are placed on the opposite side to the resistors 49 to 53 with the transistors 44 to 48 in-between.

The respective one terminals of the capacitance elements 85 to 89 are respectively coupled to the drain wirings 77. The respective other terminals are respectively coupled to the gate wirings 79 through the capacitance elements 90 to 94 and bundled through the resistors 49 to 53 and coupled to reference potential VSS.

The capacitance value of each of the capacitance elements 85 to 89 and its voltage dependence are so set that signal distortion thereby produced compensates second-order harmonic distortion. For this purpose, the impurity concentration of the low-impurity concentration silicon layer 74 in FIG. 10 is controlled to approximately 5×10¹⁷ cm⁻³ and the width of the high-impurity concentration polycrystalline silicon film 76 is designed to approximately 1/10 of the gate width of the transistors 44 to 48.

According to the third embodiment, the following can be implemented as compared with cases where none of the capacitance elements 85 to 89 is added: second-order harmonic distortion can be reduced by approximately 10 dB substantially without influence on the characteristics, such as third-harmonic waves, loss, and isolation, other than second-harmonic waves of the antenna switch 8.

### Fourth Embodiment

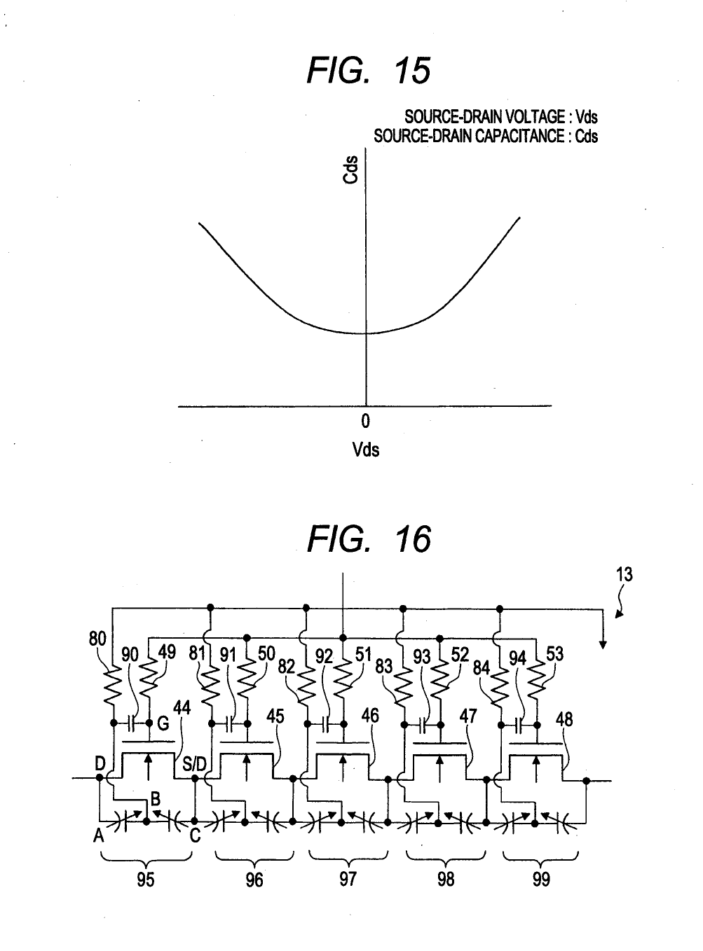

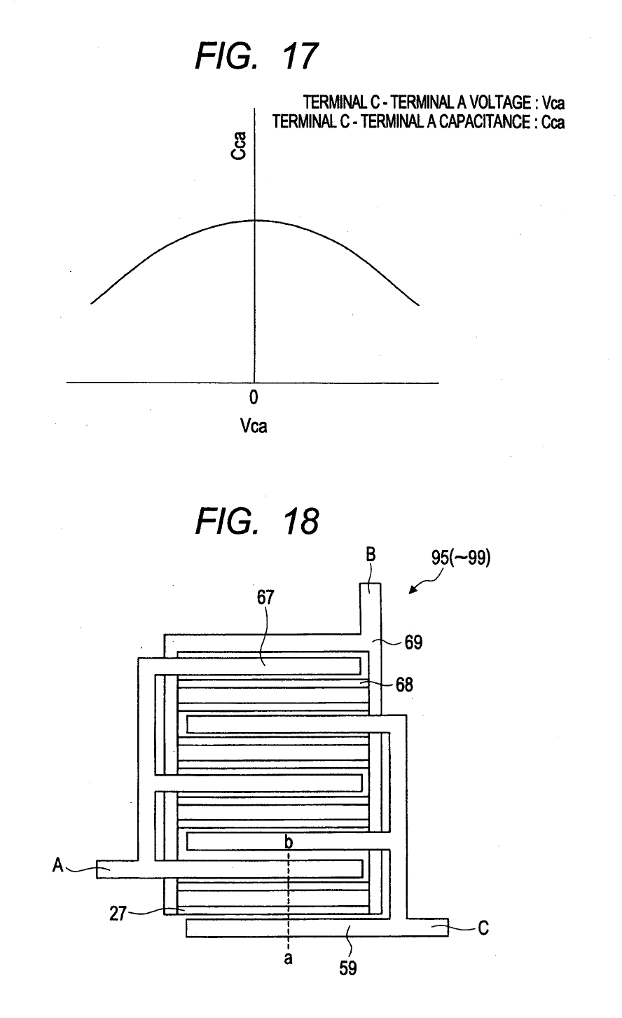

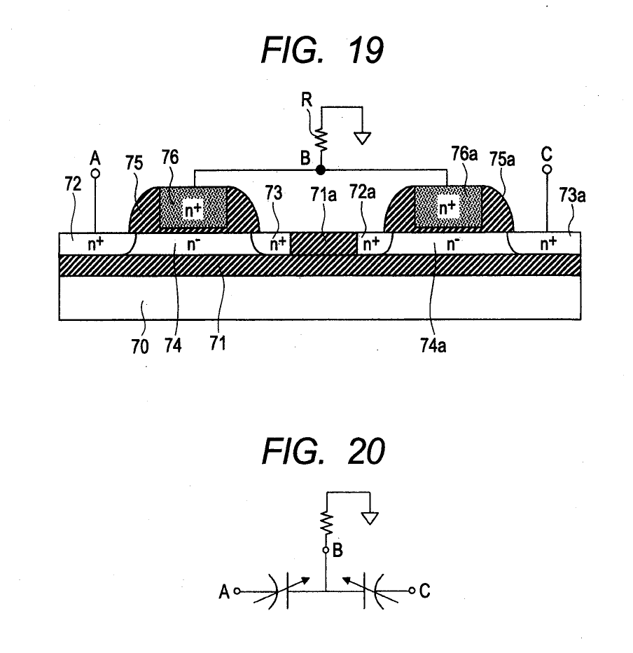

FIG. 15 is an explanatory drawing illustrating the voltage dependence of the source-drain parasitic capacitance of SOI MOSFET without a capacitive element added; FIG. 16 is a circuit diagram illustrating an example of a through MOSFET group of reception branch in the fourth embodiment of the invention; FIG. 17 is an explanatory drawing illustrating the voltage dependence of the capacitance value of a capacitance element for reducing third-order harmonic distortion provided in the through MOSFET group of reception branch in FIG. 16; FIG. 18 is an explanatory drawing illustrating an example of the layout in a capacitance element provided in the through MOSFET group of reception branch in FIG. 16; FIG. 19 is an explanatory drawing illustrating a section taken along line a-b of FIG. 18; and FIG. 20 is a symbol diagram representing the capacitance element in FIG. 18.

With respect to the fourth embodiment, description will be given to a technology for reducing third-order harmonic distortion in the antenna switch 8.

A major cause of third-order harmonic distortion is in the voltage dependence of the parasitic capacitances between the source and body and between the drain and body of a transistor formed of SOI MOSFET comprising the antenna switch 8. The source-drain parasitic capacitance comprised of a coupling of these parasitic capacitances has voltage dependence in which the capacitance is increased by voltage application regardless of the polarity of voltage as illustrated in FIG. 15. This produces odd-order harmonic distortion, especially, third-order harmonic distortion.

The antenna switch 8 is provided with a mechanism for producing a third-harmonic wave having a phase opposite to that of this third-order harmonic distortion and substantially the same amplitude as that of the same. Thus, since the original third-order harmonic distortion is canceled out, the absolute value of the third-harmonic wave can be reduced.

Specifically, a capacitance element for compensation is added to between the source and drain of a SOI MOSFET transistor of the antenna switch 8 which transistor is turned off in a desired circuit operation mode.

This capacitance element is provided with voltage dependence opposite to that of the source-drain parasitic capacitance, that is, voltage dependence in which the capacitance is reduced by voltage application regardless of the polarity of voltage. This voltage dependence produces a third-harmonic wave in an opposite phase to that of third-harmonic waves arising from the voltage dependence of source-drain parasitic capacitance. Therefore, third-order harmonic distortion can be canceled out by adjusting its amplitude. The amplitude can be optimized by adjusting the added capacitance value and its voltage dependence.

The antenna switch 8 is comprised as in FIG. 2 in relation to the first embodiment. That is, the antenna switch 8 is comprised of a shunting MOSFET group of transmission branch 10, a through MOSFET group of transmission branch 11, a shunting MOSFET group of reception branch 12, and a through MOSFET group of reception branch 13.

Also in this case, the configuration of the through MOSFET group of reception branch 13 is different from those in the first and second embodiments. As illustrated in FIG. 16, the through MOSFET group of reception branch 13 is comprised of transistors 44 to 48 each formed of SOI n-channel MOSFET, resistors 49 to 53, 80 to 84, and capacitance elements 90 to 94, 95 to 99.

The coupling configuration of the transistors 44 to 48, resistors 49 to 53, 80 to 84, and capacitance elements 90 to 94 is the same as in FIG. 13 in relation to the third embodiment. The respective drains and sources of the transistors 44 to 48 are respectively coupled with the capacitance elements 95 to 99.

These capacitance elements 95 to 99 have terminal B. The terminal B of the capacitance element 95 is coupled to the coupling portion between the resistor 80 and the capacitance element 90. Similarly, the terminals B of the other capacitance elements 96 to 99 are respectively coupled with the respective coupling portions between the resistors 81 to 84 and the capacitance elements 91 to 94.

Description will be given to the capacitance element 95 (to 99).

The capacitance element 95 (to 99) is comprised of, for example, two of the capacitance element illustrated in FIG. 10. Their gates are coupled together to obtain terminal B and a terminal is provided only at either the source or drain of each MOS capacitor and they are respectively taken as terminal A and terminal C.

The terminal B is coupled to reference potential VSS and voltages having opposite signs and the same magnitude are applied to the terminal A and the terminal C. In this case, the voltage dependence equivalent to that of the combination of two of the capacitance element illustrated in FIG. 10 is obtained. Therefore, its capacitance value shows voltage dependence in which it is reduced with increase in voltage regardless of the polarity of voltage between terminals (voltage at terminal B−voltage at terminal A) as illustrated in FIG. 17.

The magnitude of this voltage dependence can be varied by adjusting the impurity concentration of the body located under a gate oxide film. This voltage dependence of capacitance is opposite to the voltage dependence of the source-drain parasitic capacitance of MOSFET illustrated in FIG. 15 in which voltage dependence the capacitance is increased by voltage application regardless of the polarity of voltage.

Therefore, the following effect can be obtained by adjusting the impurity concentration and gate width of the capacitance element 95 (to 99) to optimize the amount of voltage change in its capacitance value: the effect of canceling out third-order harmonic distortion arising from the voltage dependence of substrate capacitance can be obtained. Since the absolute value of a capacitance value can be made relatively small by optimization, addition of this capacitive element does not have great influence on any characteristic other than the odd-order harmonic distortion characteristic.

FIG. 18 is an explanatory drawing illustrating an example of the planar structure of the capacitance element 95 (to 99).

The capacitance element 95 (to 99) is formed of the three branched MOS capacitors, described later (FIG. 19), arranged in parallel. On the left side of FIG. 18, terminal A is formed and on the right side of FIG. 18, terminal C is formed.

The terminal A is coupled to source wirings 67 formed in a comb shape from top to bottom of FIG. 18 and the terminal C is coupled to drain wirings 59 similarly formed in a comb shape from top to bottom of FIG. 18.

Between the source wirings 67 and drain wirings 59 formed in a comb shape, gate electrodes 68 are respectively formed. These gate electrodes 68 are coupled to gate wirings 69 formed both on the right side and on the left side and coupled to terminal B in common.

FIG. 19 is an explanatory drawing illustrating an example of a section taken along line a-b of FIG. 18.

The capacitance element 95 (to 99) is comprised of, for example, two MOS capacitors. On the left side and right side of the area over a high-resistance silicon substrate 70, there are respectively formed silicon oxide films (BOX oxide films) 71, 71a.

On the left side and right side of the area over the silicon oxide film 71, there are respectively formed high-impurity concentration silicon layers 72, 73 similar to the source/drain of a transistor. On the left side and right side of the area over the silicon oxide film 71a, there are respectively formed similar high-impurity concentration silicon layers 72a, 73a. Between the high-impurity concentration silicon layer 73 and the high-impurity concentration silicon layer 72a, there is formed a silicon oxide film 71 to be an insulating film.

Over the silicon oxide film 71, there is formed a low-impurity concentration silicon layer (body) 74 so that it is sandwiched between the high-impurity concentration silicon layers 72, 73. Over the silicon oxide film 71, there is similarly formed a low-impurity concentration silicon layer 74a so that it is sandwiched between the high-impurity concentration silicon layers 72a, 73a.

Over the low-impurity concentration silicon layer 74, there is formed a high-impurity concentration polycrystalline silicon film 76 to be a gate with a silicon oxide film (gate oxide film) 75 in-between. Over the low-impurity concentration silicon layer 74a, there is formed a high-impurity concentration polycrystalline silicon film 76a to be a gate with a silicon oxide film 75a in-between.

Desired voltage dependence is obtained by adjusting the impurity concentration and distribution of the low-impurity concentration silicon layers 74, 74a. The impurity concentration is approximately 1×10¹⁷ cm⁻³ to 1×10¹⁸ cm⁻³. The high-impurity concentration polycrystalline silicon films 76, 76a to be the gate of two MOS capacitors are coupled to obtain terminal B. A terminal is respectively provided only at either of the respective high-impurity concentration silicon layers (high-impurity concentration silicon layers 72, 73a) and they are respectively taken as terminal A and terminal C.

FIG. 20 illustrates a circuit diagram symbol representing the three-terminal element in the capacitance element 95 (to 99).

The terminal B is coupled to reference potential VSS or supply voltage VDD through a resistor R and the terminal A and the terminal C are respectively coupled to the source and drain of each transistor 44 to 48.

A desired absolute value of capacitance change due to voltage is obtained by adjusting the width of the gate (high-impurity concentration polycrystalline silicon films 76, 76a). The width of the gate (high-impurity concentration polycrystalline silicon films 76, 76a) is set to approximately ⅕ or below of the gate width of the transistors 44 to 48 to prevent the characteristic of the transistor to which it is added from being largely influenced.

The length of the gate (high-impurity concentration polycrystalline silicon films 76, 76a) is set to approximately 1 μm or below to prevent the resistance of the low-impurity concentration silicon layer (body) 74 from becoming prominent as the parasitic resistance of a capacitance element.

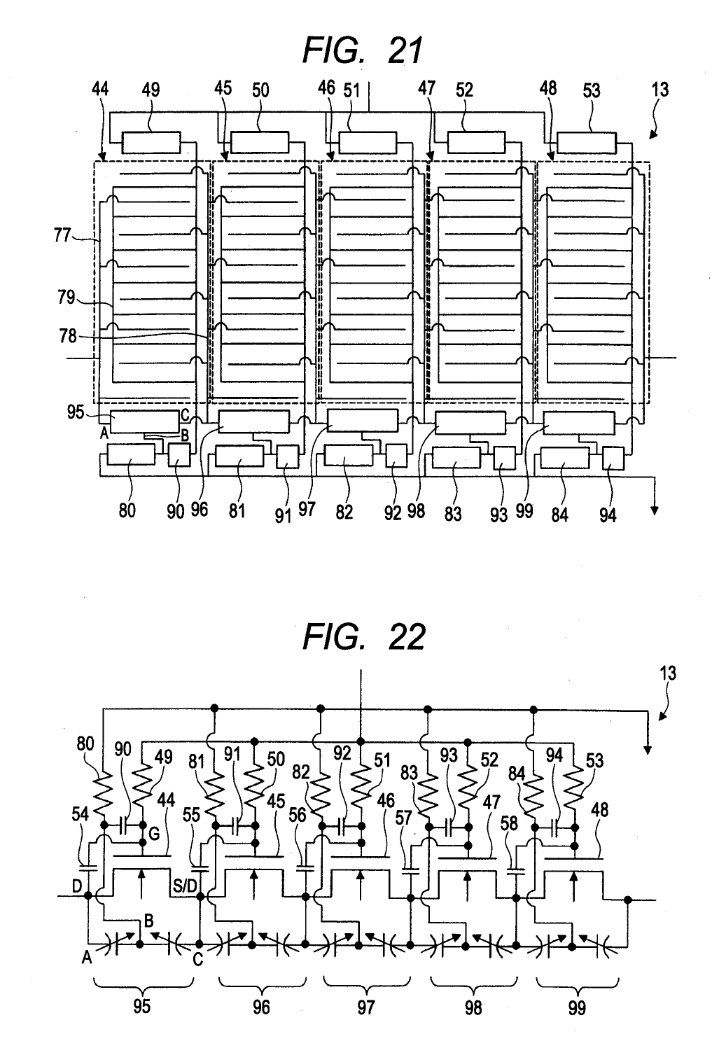

FIG. 21 is an explanatory drawing illustrating an example of the plane layout of the through MOSFET group of reception branch 13 in FIG. 16.

From left to right in the upper part of FIG. 21, the resistors 49 to 53 are arranged and under the resistors 49 to 53, the transistors 44 to 48 are respectively arranged.

Under the transistor 44 (area encircled with a broken line in the drawing), the capacitance element 95 is placed. Under the transistors 45 to 48, similarly, the capacitance elements 96 to 99 are respectively placed.

Under the capacitance element 95, the resistor 80 and the capacitance element 90 are arranged from left to right. Under the capacitance elements 96 to 99, similarly, the resistors 81 to 84 and the capacitance elements 91 to 94 are respectively arranged from left to right.

The transistor 44 is comprised of multiple branched MOSFETs arranged in parallel. The respective drains of the branches are coupled together by a comb-like drain wiring 77 and the respective sources of the branches are coupled together by a comb-like source wiring 78.

The source wiring 78 is also coupled to the respective drains of the branches of the adjacent transistor 45. The respective gates of the branches are coupled together by a ladder-structured gate wiring 79. They are bundled with the gate wirings of the transistors 44 to 48 through the resistors 49 to 53 to form a single terminal.

The capacitance elements 95 to 99, resistors 80 to 84, and capacitance elements 90 to 94 are placed on the opposite side to the resistors 49 to 53 with the transistors 44 to 48 in-between. The terminals C of the capacitance elements 95 to 99 are coupled to the source wirings 78; the terminals A are coupled to the drain wirings 77; and the terminals B are coupled to the gate wirings 79 through the capacitance elements 90 to 94 and further bundled through the resistors 80 to 84 and coupled to reference potential VSS.

The capacitance value of each of the capacitance elements 95 to 99 and its voltage dependence are so set that signal distortion thereby produced compensates third-order harmonic distortion. For this purpose, the impurity concentration of the low-impurity concentration silicon layers 74, 74a in FIG. 19 is controlled to approximately 5×10⁻¹⁷ cm⁻³. The width of the high-impurity concentration polycrystalline silicon films 76, 76a is designed to approximately 1/10 of the gate width of the transistors 44 to 48.

According to the fourth embodiment, the following can be implemented as compared with cases where none of the capacitance elements 95 to 99 is provided: third-order harmonic distortion can be reduced by approximately 10 dB or more substantially without influence on the characteristics, such as second-harmonic waves, loss, and isolation, other than second-harmonic waves of the antenna switch 8.

### Fifth Embodiment

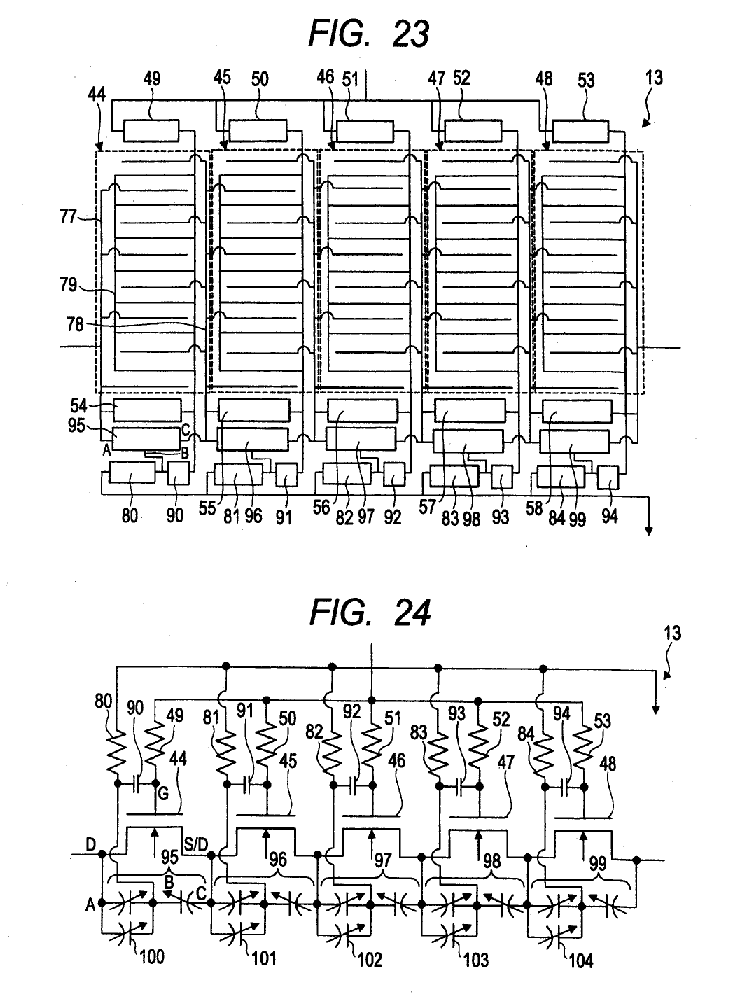

FIG. 22 is a circuit diagram illustrating an example of a through MOSFET group of reception branch in the fifth embodiment of the invention; and FIG. 23 is an explanatory drawing illustrating an example of the plane layout of the through MOSFET group of reception branch in FIG. 22.

With respect to the fifth embodiment, description will be given to a technology obtained by combining the technology for reducing second-order harmonic distortion in the first embodiment and the technology for reducing third-order harmonic distortion in the fourth embodiment.

In this case, the through MOSFET group of reception branch 13 in the antenna switch 8 is comprised of transistors 44 to 48 each formed of SOI MOSFET, resistors 49 to 53, 80 to 84, and capacitance elements 54 to 58, 90 to 99 as illustrated in FIG. 22.

The coupling configuration of the transistors 44 to 48, resistors 49 to 53, and capacitance elements 54 to 58 is the same as in FIG. 3 in relation to the first embodiment. The coupling configuration of the resistors 80 to 84 and the capacitance elements 90 to 99 is the same as in FIG. 16 in relation to the fourth embodiment. Therefore, the description thereof will be omitted.

FIG. 23 is an explanatory drawing illustrating an example of the plane layout in the through MOSFET group of reception branch 13 in FIG. 22.

From left to right in the upper part of FIG. 23, the resistors 49 to 53 are arranged and under the resistors 49 to 53, the transistors 44 to 48 are respectively arranged.

Under the transistor 44, the capacitance element 54 is placed and under the capacitance element 54, the capacitance element 95 is placed. On the left side of the area under the capacitance element 95, the resistor 80 is placed and on the right side of the resistor 80, the capacitance element 90 is placed.

Under the transistors 45 to 48, similarly, the capacitance elements 55 to 58 are respectively placed and under the capacitance elements 55 to 58, the capacitance elements 96 to 99 are respectively placed.

On the left side of the respective areas under these capacitance elements 96 to 99, the resistors 81 to 84 are respectively placed and on the right side of the resistors 81 to 84, the capacitance elements 91 to 94 are respectively placed.

Each of the transistors 44 to 48 is comprised of multiple branched MOSFETs arranged in parallel. The respective drains of the branches are coupled together by a comb-like drain wiring 77 and the respective sources of the branches are coupled together by a comb-like source wiring 78.

The source wiring 78 of the transistor 44 is also coupled to the respective drains of the branches of the adjacent transistor 45. The respective gates of the branches are coupled together by a ladder-structured gate wiring 79 and bundled with the gate wirings 79 of the transistors 44 to 48 through the resistors 49 to 53 to form a single terminal.

The capacitance elements 95 to 99, resistors 80 to 84, capacitance elements 90 to 94, and capacitance elements 54 to 58 are placed on the opposite side to the resistors 49 to 53 with the transistors 44 to 48 in-between.

The terminals A of the capacitance elements 95 to 99 are coupled to the drain wirings 77; the terminals C are coupled to the source wirings 78; and the terminals B are coupled to the gate wirings 79 through the capacitance elements 90 to 94 and further bundled through the resistors 80 to 84 and coupled to reference potential VSS. The capacitance elements 54 to 58 are coupled between the drain wirings 77 and the gate wirings 79.

The capacitance value of each of the capacitance elements 54 to 58 is so set that the following is implemented: signal distortion produced by the positive and negative asymmetric voltage dependence of source-drain parasitic capacitance arising therefrom compensates second-order harmonic distortion.

In this case, none of the capacitance elements 54 to 58 necessarily requires voltage dependence in capacitance value. The capacitance value of each of the capacitance elements 95 to 99 and its voltage dependence are so set that signal distortion thereby produced compensates third-order harmonic distortion.

For this purpose, the impurity concentration of the low-impurity concentration silicon layers 74, 74a in FIG. 19 is controlled to approximately 5×10¹⁷ cm⁻³. The width of the high-impurity concentration polycrystalline silicon films 76, 76a is designed to approximately 1/10 of the gate width of the transistors 44 to 48.

In the fifth embodiment, as a result, the following can be implemented: both second-order harmonic distortion and third-order harmonic distortion can be reduced by approximately 10 dB substantially without influence on the characteristics, such as loss and isolation, other than second-harmonic waves and third-harmonic waves of the antenna switch 8.

### Sixth Embodiment

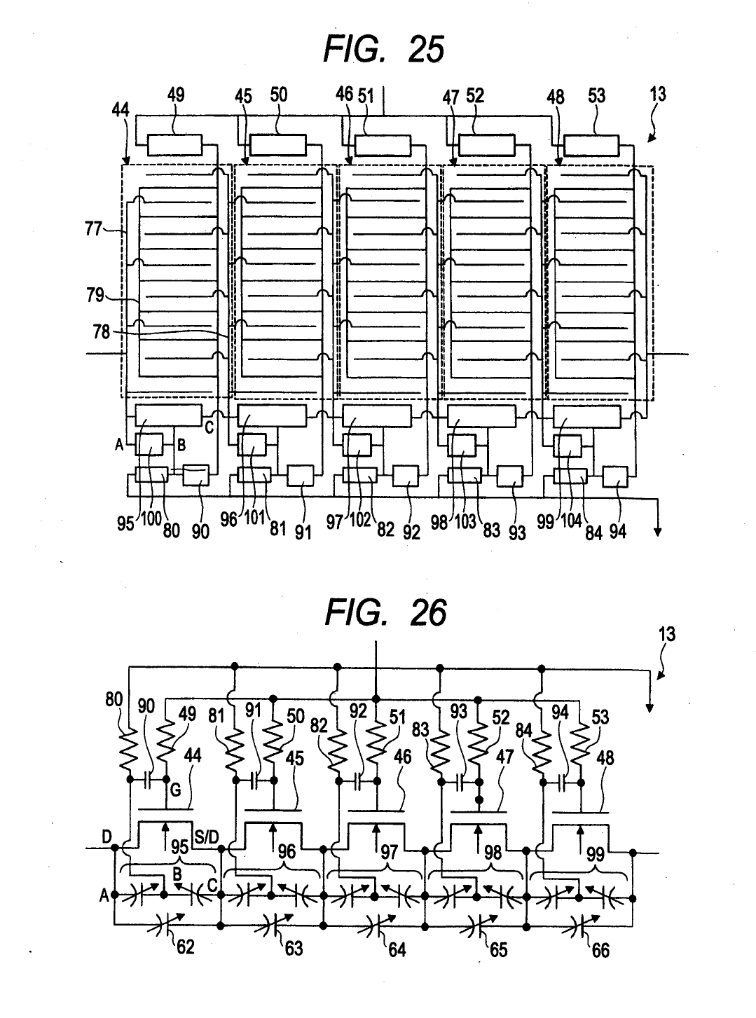

FIG. 24 is a circuit diagram illustrating an example of a through MOSFET group of reception branch in the sixth embodiment of the invention; and FIG. 25 is an explanatory drawing illustrating an example of the plane layout of the through MOSFET group of reception branch in FIG. 24.

With respect to the sixth embodiment, description will be given to another example of a technology obtained by combining a technology for reducing second-order harmonic distortion and a technology for reducing third-order harmonic distortion.

In this case, the through MOSFET group of reception branch 13 in the antenna switch 8 is comprised as illustrated in FIG. 24. That is, the through MOSFET group of reception branch 13 is comprised of transistors 44 to 48 each formed of SOI MOSFET, resistors 49 to 53, 80 to 84, capacitance elements 90 to 99, and capacitance elements 100 to 104.

The coupling configuration of the transistors 44 to 48, resistors 49 to 53, and capacitance elements 90 to 99 is the same as in FIG. 22 in relation to the fifth embodiment. The respective drains of the transistors 44 to 48 are respectively coupled with the respective one coupling portions of the capacitance elements 100 to 104. The respective other coupling portions of the capacitance elements 100 to 104 are respectively coupled with the respective terminals B of the capacitance elements 95 to 99.

FIG. 25 is an explanatory drawing illustrating an example of the plane layout in the through MOSFET group of reception branch 13 in FIG. 24.

From left to right in the upper part of FIG. 25, the resistors 49 to 53 are arranged and under the resistors 49 to 53, the transistors 44 to 48 are respectively arranged.

Under the transistor 44, the capacitance element 95 is placed and at the lower left of the capacitance element 95, the capacitance element 100 is placed. Under this capacitance element 100, the resistor 80 is placed and on the right side of the resistor 80, the capacitance element 90 is placed.

Under the transistors 45 to 48, similarly, the capacitance elements 96 to 99 are respectively placed and at the lower left of the capacitance elements 96 to 99, the capacitance elements 101 to 104 are respectively placed.

Under these capacitance elements 101 to 104, the resistors 81 to 84 are respectively placed and on the right side of the resistors 81 to 84, the capacitance elements 91 to 94 are respectively placed.

Each of the transistors 44 to 48 is comprised of multiple branched MOSFETs arranged in parallel. The respective drains of the branches are coupled together by a comb-like drain wiring 77 and the respective sources of the branches are coupled together by a comb-like source wiring 78.

The source wiring 78 of the transistor 44 is also coupled with the respective drains of the branches of the adjacent transistor 45. The respective gates of the branches are coupled together by a ladder-structured gate wiring 79 and bundled with the gate wirings 79 of the transistors 44 to 48 through the resistors 49 to 53 to form a single terminal.

The capacitance elements 95 to 99, resistors 80 to 84, and capacitance elements 90 to 94 are placed on the opposite side to the resistors 49 to 53 with the transistors 44 to 48 in-between.

The terminals A of the capacitance elements 95 to 99 are coupled to the drain wirings 77; the terminals C are coupled to the source wirings 78; and the terminals B are coupled to the gate wirings 79 through the capacitance elements 90 to 94 and further bundled through the resistors 80 to 84 and coupled to reference potential VSS.

The capacitance value of each of the capacitance elements 100 to 104 is so set that the following is implemented: signal distortion produced by the positive and negative asymmetric voltage dependence of source-drain parasitic capacitance arising therefrom compensates second-order harmonic distortion.

The capacitance value of each of the capacitance elements 100 to 104 and its voltage dependence are so set that signal distortion thereby produced compensates second-order harmonic distortion. For this purpose, the impurity concentration of the low-impurity concentration silicon layer 74 is controlled to approximately 5×10⁻¹⁷ cm⁻³. The width of the high-impurity concentration polycrystalline silicon film 76 is designed to approximately 1/10 of the gate width of the transistors 44 to 48.

The capacitance value of each of the capacitance elements 95 to 99 and its voltage dependence are so set that signal distortion thereby produced compensates third-order harmonic distortion. For this purpose, the impurity concentration of the low-impurity concentration silicon layer 74 in FIG. 19 is controlled to approximately 5×10¹⁷ cm⁻³. The width of the high-impurity concentration polycrystalline silicon films 76, 76a is designed to approximately 1/10 of the gate width of the transistors 44 to 48.

In the sixth embodiment, as a result, the following can be implemented: both second-order harmonic distortion and third-order harmonic distortion can be reduced by approximately 10 dB substantially without influence on the characteristics, such as loss and isolation, other than second-harmonic waves and third-harmonic waves of the antenna switch 8.

### Seventh Embodiment

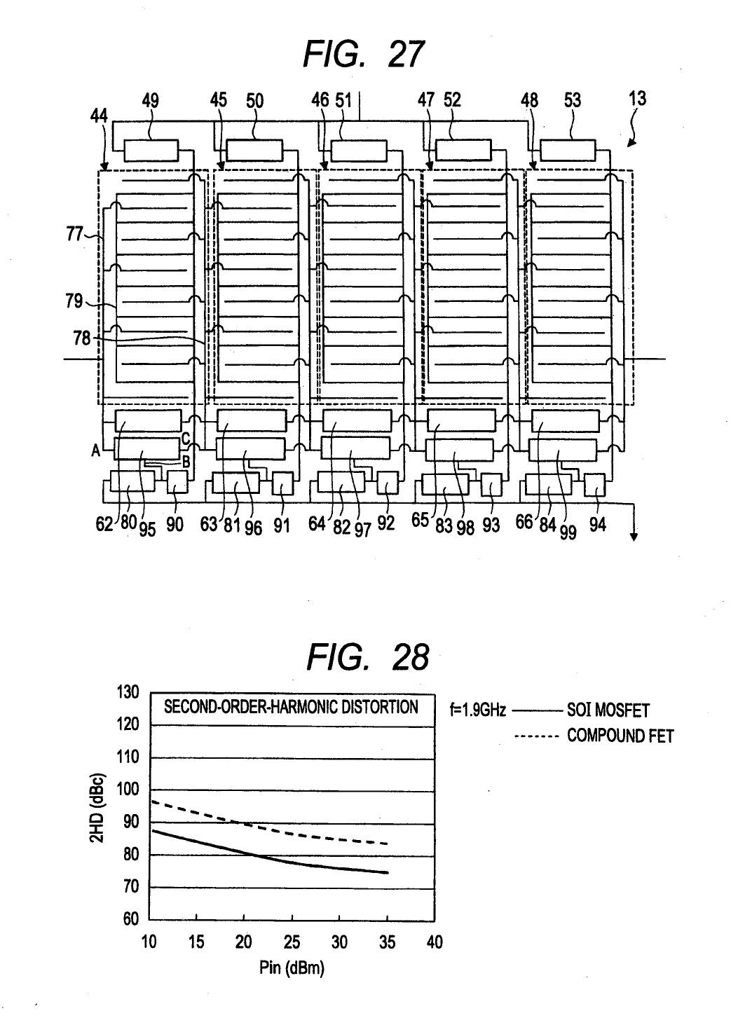

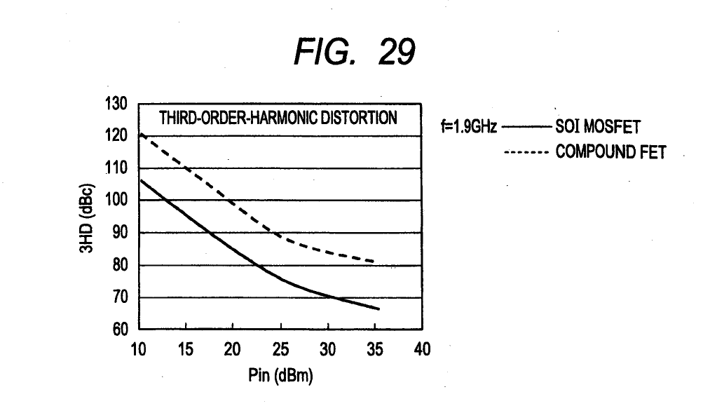

FIG. 26 is a circuit diagram illustrating an example of a through MOSFET group of reception branch in the seventh embodiment of the invention; and FIG. 27 is an explanatory drawing illustrating an example of the plane layout of the through MOSFET group of reception branch in FIG. 26.

With respect to the seventh embodiment, description will be given to further another technology obtained by combining a technology for reducing second-order harmonic distortion and a technology for reducing third-order harmonic distortion.

In this case, the through MOSFET group of reception branch 13 in the antenna switch 8 is comprised as illustrated in FIG. 26. That is, the through MOSFET group of reception branch 13 is comprised of transistors 44 to 48 each formed of SOI MOSFET, resistors 49 to 53, 80 to 84, and capacitance elements 62 to 66, 90 to 99.

The coupling configuration of the transistors 44 to 48, resistors 49 to 53, and capacitance elements 90 to 99 is the same as in FIG. 22 in relation to the fifth embodiment. The coupling configuration of the capacitance elements 62 to 66 is the same as in FIG. 7 in relation to the second embodiment.

FIG. 27 is an explanatory drawing illustrating an example of the plane layout in the through MOSFET group of reception branch 13 in FIG. 26.

From left to right in the upper part of FIG. 27, the resistors 49 to 53 are arranged and under the resistors 49 to 53, the transistors 44 to 48 are respectively arranged.

Under the transistor 44, the capacitance element 62 is placed and under the capacitance element 62, the capacitance element 95 is placed. At the lower left of this capacitance element 95, the resistor 80 is placed and on the right side of the resistor 80, the capacitance element 90 is placed.

Under the transistors 45 to 48, similarly, the capacitance elements 63 to 66 are respectively placed and under the capacitance elements 63 to 66, the capacitance elements 96 to 99 are respectively placed.

At the lower left of these capacitance elements 96 to 99, the resistors 81 to 84 are respectively placed and on the right side of the resistors 81 to 84, the capacitance elements 91 to 94 are respectively placed.

The capacitance elements 62 to 66, resistors 80 to 84, capacitance elements 90 to 94, and capacitance elements 95 to 99 are placed on the opposite side to the resistors 49 to 53 with the transistors 44 to 48 in-between.

The terminals A of the capacitance elements 95 to 99 are coupled to the drain wirings 77; the terminals C are coupled to the source wirings 78; and the terminals B are coupled to the gate wirings 79 through the capacitance elements 90 to 94 and further bundled through the resistors 80 to 84 and coupled to reference potential VSS. The capacitance elements 62 to 66 are coupled between the drain wirings 77 and the source wirings 78.

The capacitance value of each of the capacitance elements 62 to 66 and its voltage dependence are so set that signal distortion thereby produced compensates second-order harmonic distortion. For this purpose, the impurity concentration of the low-impurity concentration silicon layer 74 in FIG. 10 is controlled to approximately 5×10¹⁷ cm⁻³. The width of the high-impurity concentration polycrystalline silicon film 76 is designed to approximately 1/10 of the gate width of the transistors 44 to 48.

The capacitance value of each of the capacitance elements 95 to 99 and its voltage dependence are so set that signal distortion thereby produced compensates third-order harmonic distortion.

In the seventh embodiment, as a result, both second-order harmonic distortion and third-order harmonic distortion can be reduced by approximately 10 dB substantially without influence on the characteristics, such as loss and isolation, other than second-harmonic waves and third-harmonic waves of the antenna switch 8.

The invention is suitable for technologies for reducing second-order harmonic distortion and second-order harmonic distortion in an antenna switch configured using SOI MOSFETs.

1. A semiconductor integrated circuit device comprising: at least one antenna terminal; at least one transmission terminal; and at least one reception terminal, and provided with an antenna switch for switching signal paths,
wherein the antenna switch includes:
a first transistor group coupled between the antenna terminal and the transmission terminal;
a second transistor group coupled between the antenna terminal and the reception terminal;
a third transistor group coupled between the transmission terminal and reference potential;
a fourth transistor group coupled between the reception terminal and reference potential; and
a first capacitance element,
wherein each of the first to fourth transistor groups is comprised of one or more transistors coupled in series, and
wherein the first capacitance element is coupled between the gate and source or gate and drain of at least one of the transistors comprising the first to fourth transistor groups.

2. The semiconductor integrated circuit device according to claim 1,
wherein the first capacitance element is coupled to a transistor provided in the second transistor group.

3. The semiconductor integrated circuit device according to claim 1,
wherein the first capacitance element is formed over an SOI substrate.

4. A semiconductor integrated circuit device comprising: at least one antenna terminal; at least one transmission terminal; and at least one reception terminal, and provided with an antenna switch for switching signal paths,
wherein the antenna switch includes:
a first transistor group coupled between the antenna terminal and the transmission terminal;
a second transistor group coupled between the antenna terminal and the reception terminal;
a third transistor group coupled between the transmission terminal and reference potential;
a fourth transistor group coupled between the reception terminal and reference potential;
a second capacitance element; and
a third capacitance element,
wherein each of the first to fourth transistor groups is comprised of one or more transistors coupled in series,
wherein the second capacitance element is coupled between the gate and source of at least one of the transistors comprising the first to fourth transistor groups,
wherein the third capacitance element is coupled between the gate and drain of the transistor, and
wherein the second capacitance element and the third capacitance element are different from each other in capacitance value.

5. The semiconductor integrated circuit device according to claim 4,
wherein the second and third capacitance elements are formed over an SOI substrate.

6. The semiconductor integrated circuit device according to claim 4,
wherein the second and third capacitance elements are coupled to a transistor provided in the second transistor group.

7. A semiconductor integrated circuit device comprising: at least one antenna terminal; at least one transmission terminal; and at least one reception terminal, and provided with an antenna switch for switching signal paths,
wherein the antenna switch includes:
a first transistor group coupled between the antenna terminal and the transmission terminal;
a second transistor group coupled between the antenna terminal and the reception terminal;
a third transistor group coupled between the transmission terminal and reference potential,
a fourth transistor group coupled between the reception terminal and reference potential; and
a fourth capacitance element,
wherein each of the first to fourth transistor groups is comprised of one or more transistors coupled in series, and
wherein the fourth capacitance element has voltage dependence in capacitance value and is coupled between the source and drain of at least one of the transistors comprising the first to fourth transistor groups.

8. The semiconductor integrated circuit device according to claim 7,
wherein the fourth capacitance element is formed over an SOI substrate.

9. The semiconductor integrated circuit device according to claim 7,
wherein the fourth capacitance element is comprised of two MOS capacitors coupled together and the coupling portion between the two MOS capacitors is coupled to reference potential or supply voltage through a resistor.

10. The semiconductor integrated circuit device according to claim 9,
wherein each of the MOS capacitors is comprised of a gate electrode, a gate oxide film located directly under the gate electrode, and a silicon substrate, the silicon substrate area around the gate electrode being made higher in impurity concentration than the silicon substrate area located directly under the gate electrode, the gate electrodes being electrically coupled together to obtain one gate terminal, and one terminal being respectively provided in the high-impurity concentration silicon substrate area around each of the gate electrodes.

11. The semiconductor integrated circuit device according to claim 9,
wherein the antenna switch includes a fifth capacitance element,
wherein the fifth capacitance element has:
one coupling portion coupled to the gate of at least one of the transistors comprising the first to fourth transistor groups; and
the other coupling portion coupled to the node of the coupling portion between the two MOS capacitors of the fourth capacitance element.

12. The semiconductor integrated circuit device according to claim 7,
wherein the fourth capacitance element is coupled to a transistor provided in the second transistor group.

13. A semiconductor integrated circuit device comprising: at least one antenna terminal; at least one transmission terminal; and at least one reception terminal, and provided with an antenna switch for switching signal paths,
wherein the antenna switch includes:
a first transistor group coupled between the antenna terminal and the transmission terminal;
a second transistor group coupled between the antenna terminal and the reception terminal;
a third transistor group coupled between the transmission terminal and reference potential;
a fourth transistor group coupled between the reception terminal and reference potential; and
a sixth capacitance element,
wherein each of the first to fourth transistor groups is comprised of one or more transistors coupled in series, and
wherein the sixth capacitance element has:
one coupling portion coupled to the source or drain of at least one of the transistors comprising the first to fourth transistor groups; and
the other coupling portion coupled to reference potential through a resistor.

14. The semiconductor integrated circuit device according to claim 13,
wherein the sixth capacitance element is formed over an SOI substrate.

15. The semiconductor integrated circuit device according to claim 13,
wherein the antenna switch includes a seventh capacitance element, and
wherein the seventh capacitance element has:
one coupling portion coupled to the gate of at least one of the transistors comprising the first to fourth transistor groups; and
the other coupling portion coupled to the coupling node between the fifth capacitance element and the resistor.

16. The semiconductor integrated circuit device according to claim 15,
wherein the sixth capacitance element is coupled to a transistor provided in the second transistor group.

17. The semiconductor integrated circuit device according to claim 14,
wherein the seventh capacitance element is formed over an SOI substrate.

18. The semiconductor integrated circuit device according to claim 11,
wherein the fifth capacitance element is a MOS capacitor.

19. The semiconductor integrated circuit device according to claim 15,
wherein the seventh capacitance element is a MOS capacitor.

20. The semiconductor integrated circuit device according to claim 1,
wherein a transistor comprising the first to fourth transistor groups is formed over an SOI substrate.
